(19) United States
(12) Patent Application Publication
(10) Pub. No.: US 2025/0357408 A1
(43) Pub. Date: Nov. 20, 2025

(54) STACKED CHIP PACKAGE STRUCTURE AND METHOD FOR FORMING THE SAME

(71) Applicant: HEFEI SMAT TECHNOLOGY CO. LTD., HEFEI CITY, ANHUI PROVINCE (CN)

(72) Inventor: Xiaochun TAN, HEFEI CITY, ANHUI PROVINCE (CN)

(21) Appl. No.: 19/176,469

(22) Filed: Apr. 11, 2025

(30) Foreign Application Priority Data
May 20, 2024 (CN) 202410619647.6

(51) Int. Cl. H01L 23/00; H01L 23/31; H01L 25/00; H01L 25/11

(52) U.S. Cl. CPC H01L 24/24; H01L 23/3107; H01L 24/19; H01L 24/25; H01L 24/32; H01L 24/73; H01L 25/117; H01L 25/50; H01L 2224/19; H01L 2224/24145; H01L 2224/2518; H01L 2224/32145; H01L 2224/32245; H01L 2224/73267

(57) ABSTRACT

The present disclosure describes a stacked chip package structure and a method for forming the same. In the stacked chip package structure, a third encapsulant is disposed below a first encapsulant and encapsulates a first wiring layer. The first wiring layer electrically couples a first inner pad of a first chip and a first inner pad of a second chip to a first external pad. The first wiring layer penetrates the third encapsulant and is in direct contact with the first inner pad of the first chip and the first external pad. This stacked chip package structure can save space for mounting and wiring on a printed circuit board, and the ultra-thin third wiring layer rapidly transfers the operational heat of the chips to the outside of the package structure, improving heat dissipation and enhancing device reliability.

### CROSS-REFERENCE TO PRIOR APPLICATIONS

This application claims priority to Chinese Patent Application No. 202410619647.6, filed on May 20, 2024, titled “PACKAGE STRUCTURE WITH STACKED PARALLEL MOS POWER DEVICES AND PACKAGING METHOD THEREOF,” the contents of which are incorporated herein by reference, including the entire specification, claims, drawings, and abstract.

### TECHNICAL FIELD

The present disclosure belongs to the technical field of chip packaging, and

particularly relates to a stacked chip package structure and a method for forming the same.

### BACKGROUND

With the technological development towards miniaturization of power integrated circuits and devices, power semiconductor devices, as one of the core electronics of power integrated circuits, also present requirements for high integration, miniaturization, high performance, and low cost. Power semiconductor devices can effectively achieve circuit output short-circuit protection. MOS transistor chips are a type of power semiconductor device, which are abbreviations of metal-oxide-semiconductor field-effect transistors, typically made from silicon materials.

The structure of a MOS transistor chip mainly includes three parts: gate (G), source(S), and drain (D). The gate is the control terminal of the MOS transistor chip. By controlling the change of gate voltage, on and off states state of the MOS transistor can be adjusted. The source and drain are two electrodes of the MOS transistor chip, and the current between the source and drain controls on and off states of the MOS transistor.

For some amplifier circuits, multiple MOS transistor chips need to be connected in parallel. The conventional process is to solder each packaged MOS transistor chip on a working area of a printed circuit board, tiling on the printed circuit board, and achieving parallel connection of multiple MOS transistors through wirings on the printed circuit board. This undoubtedly requires a large space on the printed circuit board, making the overall size larger, which is not suitable for some installation occasions with limited space. Therefore, there is an urgent need to design a chip stacked package structure and packaging method with a small package size and parallel connection.

### SUMMARY

To solve the problems in the prior art, the present disclosure provides a stacked chip package structure and a method for forming the same.

According to one aspect of the present disclosure, there is provided a stacked chip package structure comprising: a first encapsulant and a second encapsulant stacked on the first encapsulant, the first encapsulant encapsulating a first chip and the second encapsulant encapsulating a second chip, each of the first chip and the second chip having a first surface and a second surface opposite to the first surface, and a first inner pad on the first surface and a third inner pad on the second surface, wherein the second surface of the first chip faces the second surface of the second chip face; and a third encapsulant disposed below the first encapsulant and encapsulating a first wiring layer, the first wiring layer electrically coupling the first inner pad of the first chip and the first inner pad of the second chip to a first external pad, wherein the first wiring layer penetrates the third encapsulant and is in direct contact with the first inner pad of the first chip and the first external pad.

Optionally, it further comprises: a second wiring layer disposed above the first encapsulant and coupling the third inner pad of the first chip with the third inner pad of the second chip; and a third conductive via penetrating the first encapsulant and the third encapsulant, the third conductive via coupling the second wiring layer with a third external pad.

Optionally, it further comprises: a third wiring layer disposed above the second encapsulant, wherein a first wiring of the third wiring layer is coupled to the first inner pad of the second chip; and a first conductive via penetrating the first encapsulant and the second encapsulant, the first conductive via coupling the first wiring of the third wiring layer with the first wiring layer.

Optionally, the first conductive via comprises a first section and a second section, the first section penetrating the first encapsulant and the second section penetrating the second encapsulant.

Optionally, each of the first chip and the second chip has a second inner pad on the first surface, and a second wiring of the third wiring layer is coupled with the second inner pad of the second chip.

Optionally, it further comprises: a third conductive via penetrating the first encapsulant and the second encapsulant, the third conductive via coupling the second wiring of the third wiring layer to the first wiring layer.

Optionally, the third conductive via comprises a first section and a second section, the first section penetrating the first encapsulant and the second section penetrating the second encapsulant, respectively.

Optionally, the first chip and the second chip are a first MOS transistor and a second MOS transistor, respectively.

According to another aspect of the present disclosure, there is provided a method of forming a stacked chip package structural, comprising: forming a first encapsulant to encapsulate a first chip; forming a third encapsulant to encapsulate a first wiring layer; and forming a second encapsulant to encapsulate a second chip, wherein each of the first chip and the second chip has a first surface and a second surface opposite to the first surface, a first inner pad on the first surface, and a third inner pad on the second surface, and the second surface of the first chip faces the second surface of the second chip, wherein the first wiring layer penetrates the third encapsulant and is in direct contact with the first inner pad of the first chip and a first external pad.

Optionally, the step of forming the first encapsulant to encapsulate the first chip comprises: providing a first substrate; attaching the second surface of the first chip on the first substrate; and forming the first encapsulant to cover the first chip and expose the first surface of the first chip.

Optionally, the step of forming the third encapsulant to encapsulate the first wiring layer comprises: forming the first wiring layer on a surface of the first encapsulant opposite the first substrate; forming the third encapsulant on the first encapsulant, the third encapsulant covering the first wiring layer; and thinning the third encapsulant so that the first wiring layer penetrates the third encapsulant.

Optionally, he step of forming the second encapsulant to encapsulate the second chip comprises: removing the first substrate; attaching the exposed surface of the third encapsulant on a second substrate; securing the second chip on the first encapsulant; and forming the second encapsulant to cover the second chip and expose the first surface of the second chip.

Optionally, after attaching the exposed surface of the third encapsulant on the second substrate, it further comprises: forming a second wiring layer on a surface of the first encapsulant opposite the second substrate; and forming a third conductive via penetrating the first encapsulant and the third encapsulant.

Optionally, it further comprises: forming a third wiring layer on the exposed surface of the second encapsulant; and forming a fourth encapsulant to cover the third wiring layer.

Optionally, each of the first chip and the second chip has a second inner pad on the first surface, and a second wiring of the third wiring layer is coupled to the second inner pad of the second chip, the method further comprises: forming a first conductive via penetrating the first encapsulant and the second encapsulant to couple a first wiring of the third wiring layer to the first wiring layer; and/or forming a third conductive via penetrating the first encapsulant and the second encapsulant to couple the second wiring of the third wiring layer to the first wiring layer.

Optionally, the first chip and the second chip are a first MOS transistor and a second MOS transistor, respectively.

Optionally, the first inner pad is a source pad of the first MOS transistor or the second MOS transistor, and the third inner pad is a drain pad of the first MOS transistor or the second MOS transistor.

Optionally, any encapsulant in the stacked chip package structure is formed by: forming the encapsulant by injection molding using a plastic material; and curing and shaping the plastic material by a molding process.

Optionally, any wiring layer in the stacked chip package structure is formed by electroplating metal.

According to the embodiments of the present disclosure, in the stacked chip package structure and its manufacturing method, two chips are stacked in a back-to-back manner and a wiring layer in the stacked package structure is used for interconnection between the inner pads of the two chips, and interconnection between the inner pads of the two chips and the external pads. On the working area of the printed circuit board, the stacked package structure of the two chips can occupy only the area of a single chip and have only the external pads of a single chip. This not only reduces the package size and saves working space on the printed circuit board but also reduces the number of external pads of the package structure, improving work efficiency in a bonding process.

Moreover, the stacked chip package structure and the method therefor are particularly suitable for applications with strict size requirements and high-performance parallel connections. With the above package structure and method, not only is the parallel connection of the first chip and the second chip achieved, but the connection of the two chips is completed in the packaging stage, which greatly improves production efficiency, reduces manufacturing costs, and ensures that the packaged chips have good electrical performance and reliability. The package structure and method are capable of stable operation in various working environments, particularly suitable for automotive electronics, consumer electronics, and industrial control fields.

Furthermore, the stacked chip package structure and the method therefor include a third encapsulant disposed below the first encapsulant and a first wiring layer penetrating the third encapsulant. The first wiring layer is the interconnection layer of the first inner pads of the first chip and the second chip, as well as the intermediate layer between the first inner pad of the first chip and the first external pad. The first wiring layer leads the first inner pads of the two chips to the first external pad, thereby achieving the connection between the chips and the external circuit. Compared with the conventional method of forming a wiring layer inside the encapsulant, the present disclosure uses a wiring layer penetrating the third encapsulant. Compared with the conventional method of forming a wiring layer inside the encapsulant, the third wiring layer in the present disclosure has a more direct heat conduction path, reducing the retention time of heat inside the third encapsulant, which can improve heat dissipation performance. The third wiring layer is used for both electrical connection paths and heat conduction paths, effectively conducting the heat generated by the chips to the outside of the encapsulant, thereby reducing the working temperature of the chips and extending their service life.

### BRIEF DESCRIPTION OF THE DRAWINGS

FIG. 1 shows a perspective view of the stacked chip package structure according to a first embodiment of the present disclosure;

FIGS. 2A and 2B show a top view and a sectional view of the stacked chip package structure according to the first embodiment of the present disclosure, respectively;

FIG. 3 shows a flowchart of the method for forming the stacked chip package structure according to a second embodiment of the present disclosure;

FIGS. 4A to 4N show sectional views of various stages of the method for forming the stacked chip package structure according to the second embodiment of the present disclosure.

### DETAILED DESCRIPTION

To better understand the objectives, structure, and functions of the embodiments of the present disclosure, a further detailed description of a stacked chip package structure and method proposed by the embodiments of the present disclosure is provided below in conjunction with the drawings.

Chips are designed according to the actual needs of the product. Some chips consist of a single MOS transistor, while others integrate multiple MOS transistors. In electronic devices, multi-channel MOS transistor chips can be used in power amplifier circuits, filter circuits, switch circuits, etc.

The conventional MOS transistors are generally packaged separately and then installed in the corresponding area of the PCB. For electronic circuits composed of multiple MOS transistor chips, they are installed first and then connected in series or parallel on the PCB. Such a structure requires a large space for device mounting and circuit wiring on the PCB, making the overall size of the electronic circuit larger, which does not meet packaging requirements.

According to the stacked chip package structure according to the present disclosure, two chips are stacked in a vertical direction, and a wiring layer inside the package structure is used to achieve electrical connection between the chips. This not only significantly reduces the area occupied by the chips on the printed circuit board but also simplifies the circuit wiring design, improving packaging efficiency and reliability. Regardless of the type of MOS transistor or the number of MOS transistors integrated on the chip, the stacked chip package structure according to the present disclosure can be used. The following explains the claimed parallel package structure using two N-channel enhancement-type MOS transistors as an example.

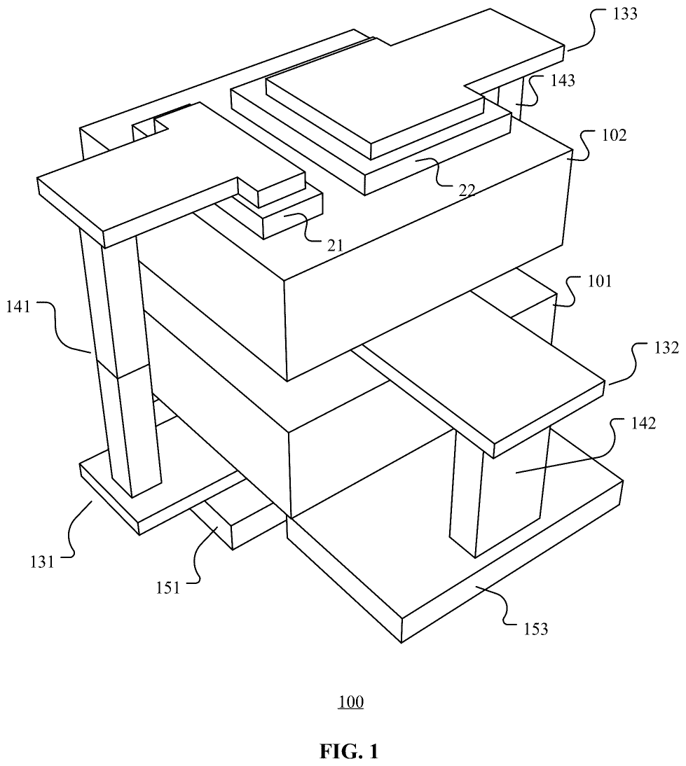

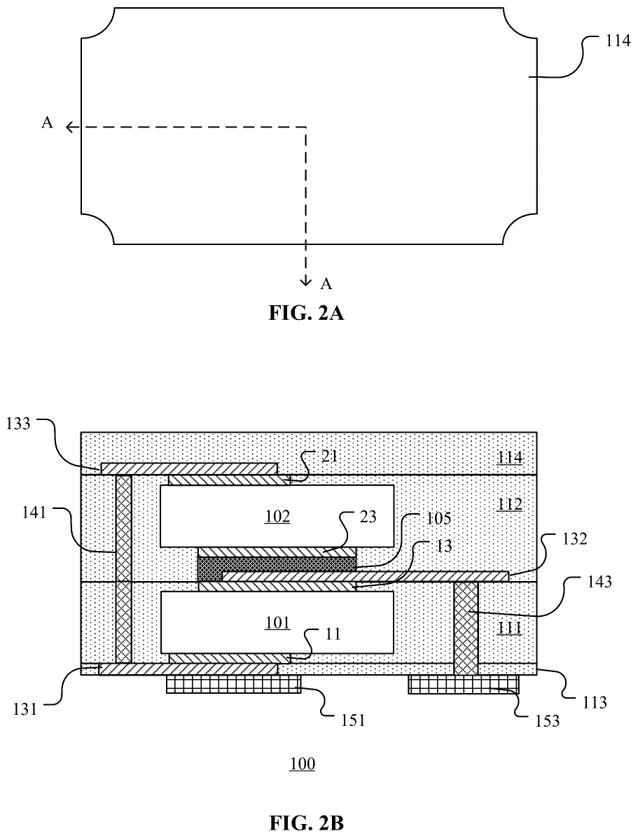

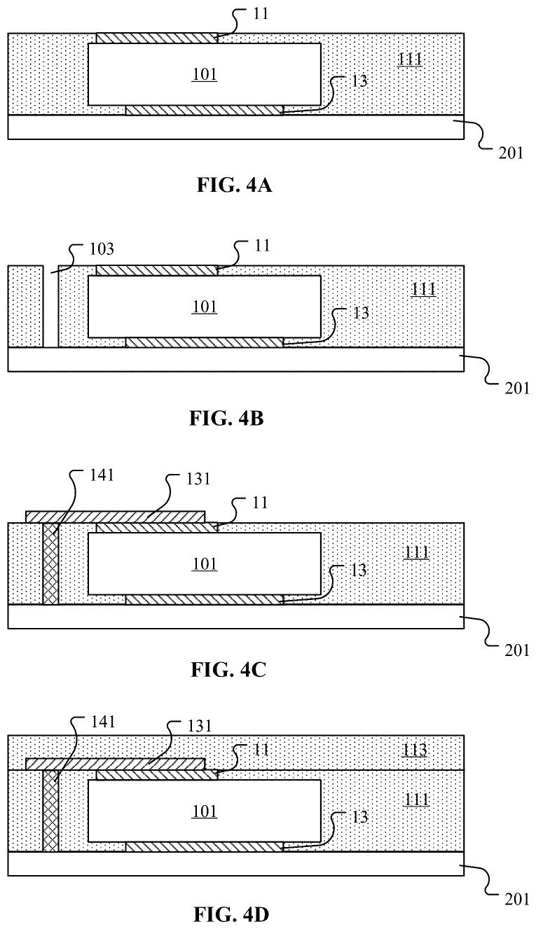

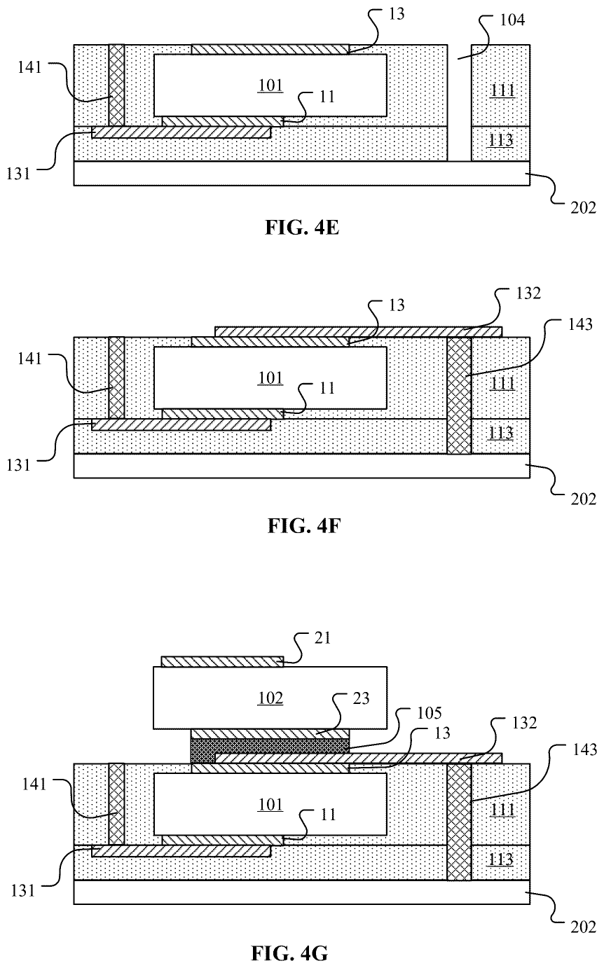

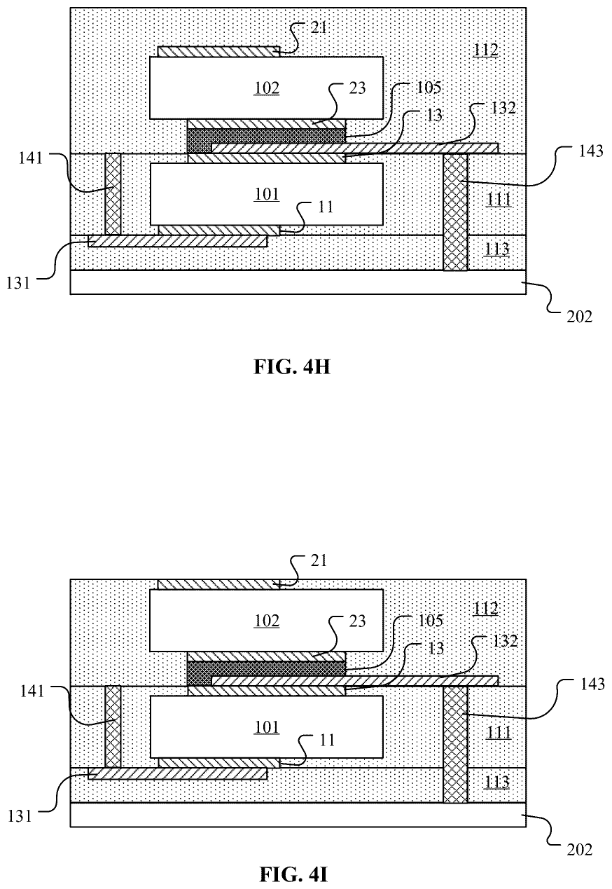

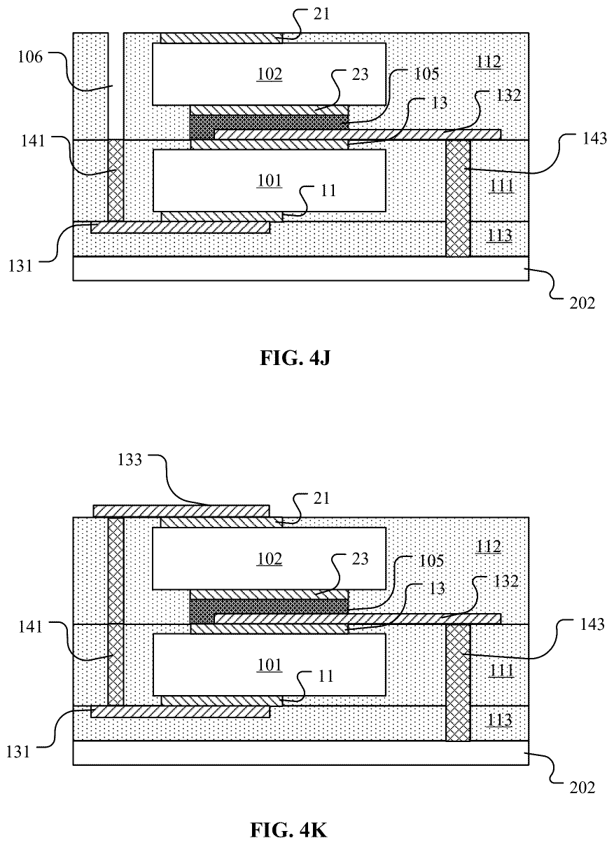

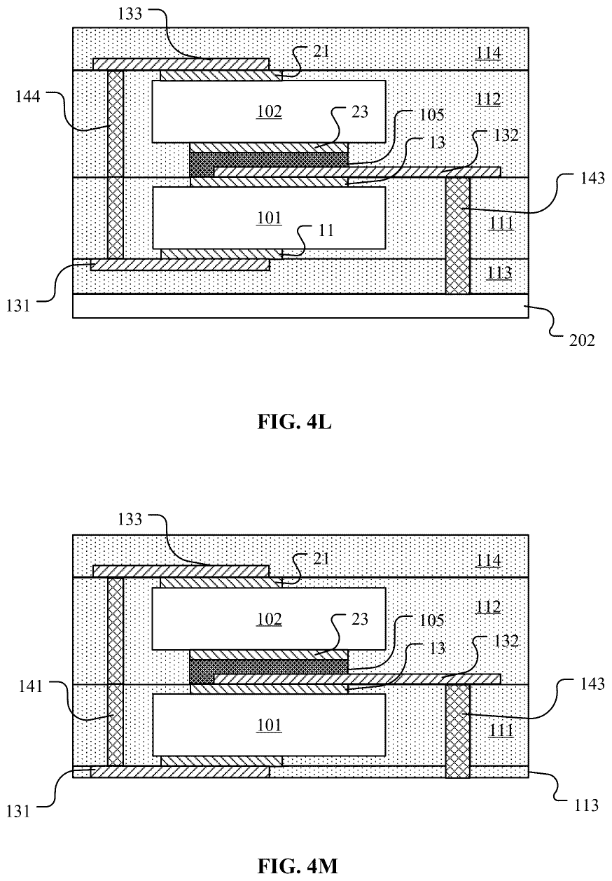

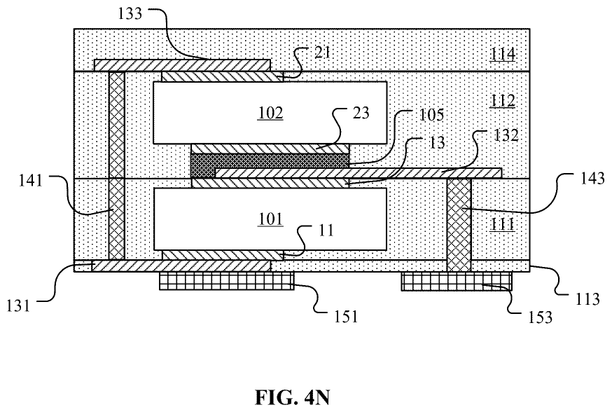

Please refer to FIG. 1, FIG. 2A, and FIG. 2B, which respectively show a perspective view, a top view, and a sectional view of the stacked chip package structure according to the first embodiment of the present disclosure. For clarity, the first encapsulant 111 for encapsulating the first chip 101 and the second encapsulant 112 for encapsulating the second chip 102 are not shown in FIG. 1. In the top view of FIG. 2A, the line AA indicates the position of the sectional view shown in FIG. 2B, and FIGS. 4A to 4N.

The stacked chip package structure 100 includes a first encapsulant 111, a second encapsulant 112, a third encapsulant 113, and a fourth encapsulant 114. The second encapsulant 112 is stacked above the first encapsulant 111. The first chip 101 and the second chip 102 are encapsulated within the first encapsulant 111 and the second encapsulant 112, respectively. Both the first chip 101 and the second chip 102 are chips having MOS transistors, which can have a single MOS transistor or integrate multiple MOS transistors. The present disclosure uses a single MOS transistor as an example, with the second surface of the first chip 101 facing the second surface of the second chip 102. The third encapsulant 113 is disposed below the first encapsulant 111, and the first external pad 151, the second external pad 152, and the third external pad 153 are formed on the lower surface of the third encapsulant 113. The fourth encapsulant 113 is disposed above the second encapsulant 112, covering the wiring layer on the upper surface of the second encapsulant 112.

Each of the first chip 101 and the second chip 102 has a single MOS transistor or integrate multiple MOS transistors. The present disclosure uses a single MOS transistor as an example, with the second surface of the first chip 101 facing the second surface of the second chip 102. The first surface of the first chip 101 is formed with a first inner pad 11 and a second inner pad 12, and the second surface is formed with a third inner pad 13. For example, the first inner pad 11, the second inner pad 12, and the third inner pad 13 are the source pad, gate pad, and drain pad of the MOS transistor, respectively. The first surface of the second chip 102 is formed with a first inner pad 21 and a second inner pad 22, and the second surface is formed with a third inner pad 23. For example, the first inner pad 21, the second inner pad 22, and the third inner pad 23 are the source pad, gate pad, and drain pad of the MOS transistor, respectively.

Furthermore, the stacked chip package structure 100 also includes a first wiring layer 131 and a second wiring layer 133 disposed on the opposite surface of the first encapsulant 111, and a third wiring layer 133 disposed on the upper surface of the second encapsulant 112. The second wiring layer 132 is disposed between the second surface of the first chip 101 and the second surface of the second chip 102.

The second wiring layer 132 includes at least one wiring, connecting the third inner pad 13 of the first chip 101 with the third inner pad 23 of the second chip 102. Preferably, the third inner pad 13 of the first chip 101 is exposed on its second surface, and the second wiring layer 132 is in direct contact with the third inner pad 13 of the first chip 101. The third inner pad 23 of the second chip 102 is bonded and secured on the second wiring layer 132 using a conductive adhesive 105. The second surface of the second chip 102 can also be coated with an insulating adhesive, bonded and secured on the upper surface of the lower encapsulant 111. The third wiring layer 133 includes multiple wirings. The first inner pad 21 and the second inner pad 22 of the second chip 102 are exposed on its first surface, and the first wiring and the second wiring of the third wiring layer 133 are in direct contact with the first inner pad 101 and the second inner pad 102 of the second chip 102, respectively.

Furthermore, the stacked chip package structure 100 also includes a first conductive via 141 and a second conductive via 142 penetrating the first encapsulant 111 and the second encapsulant 112, and a third conductive via 143 penetrating the first encapsulant 111 and the third encapsulant 113. The first conductive via 141 and the second conductive via 142 can each be formed integrally or formed by connecting two sections penetrating the first encapsulant 111 and the second encapsulant 112, respectively. The third conductive via 143 can be formed integrally or formed by connecting two sections penetrating the first encapsulant 111 and the third encapsulant 113, respectively.

The multiple wirings of the first wiring layer 131 are connected to the corresponding wirings in the third wiring layer 133 via the first conductive via 141 and the second conductive via 142, respectively. The first wiring layer 131 penetrates the third wiring layer 113, with its upper surface in contact with the first inner pad 11 and the second inner pad 12 of the first chip 101, and its lower surface in contact with the first external pad 151 and the second external pad 152. Therefore, the first inner pad 11 of the first chip 101 and the first inner pad 21 of the second chip 102 share the first external pad 151, and the second inner pad 12 of the first chip 101 and the second inner pad 22 of the second chip 102 share the first external pad 152. The second wiring layer 132 is directly coupled to the third external pad 153 via the third conductive via 143. Therefore, the first chip 101 and the second chip 102 share the external pads 151 to 153 for electrical connection with the external circuit.

According to the stacked chip package structure of the above embodiment, a third encapsulant is disposed below the first encapsulant and a first wiring layer penetrates the third encapsulant. The first wiring layer is the interconnection layer of the first inner pads of the first chip and the second chip, as well as the intermediate layer between the first inner pad of the first chip and the first external pad. The first wiring layer leads the first inner pads of the two chips to the first external pad, thereby achieving the connection between the chips and the external circuit. Compared with the conventional method of forming a wiring layer inside the encapsulant, the present disclosure uses a wiring layer penetrating the third encapsulant. Compared with the conventional method of forming a wiring layer inside the encapsulant, the third wiring layer in the present disclosure has a more direct heat conduction path, reducing the retention time of heat inside the third encapsulant, which can improve heat dissipation performance. The third wiring layer is used for both electrical connection paths and heat conduction paths, effectively conducting the heat generated by the chips to the outside of the encapsulant, thereby reducing the working temperature of the chips and extending their service life.

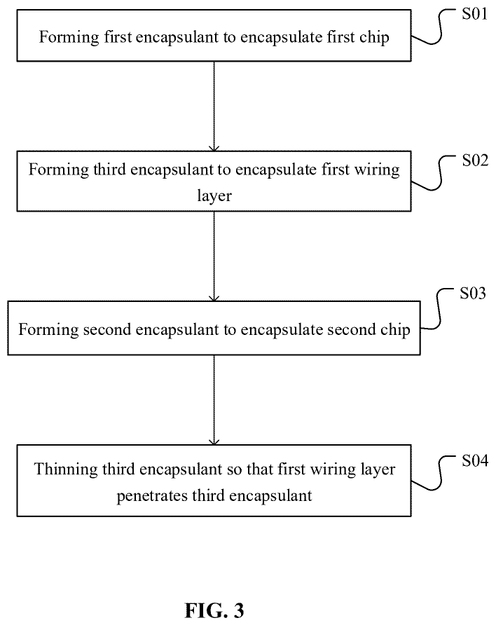

FIG. 3 shows a flowchart of the method for forming the stacked chip package structure according to a second embodiment of the present disclosure. This packaging method is used to form the stacked chip package structure 100 shown in FIG. 1 and FIGS. 2A and 2B.

In step S01, a first encapsulant 111 is formed to encapsulate the first chip 101. The first chip 101 has a first surface and a second surface opposite to each other, and a first inner pad 11 and a second inner pad 12 disposed on the first surface, and a third inner pad 13 disposed on the second surface.

In this step, the second surface of the first chip 101 is bonded to a first substrate, and then a first encapsulant 110 is formed by injection molding using a plastic material, covering the first chip 101 and exposing its first surface.

In step S02, a third encapsulant 113 is formed below the first encapsulant 111 to encapsulate a first wiring layer 131.

In this step, a metal layer is formed on the surface of the first encapsulant 111 opposite the first substrate by electroplating, and then the metal layer is etched to form a wiring pattern, thereby forming the first wiring layer 131. The first wiring layer 131 is in contact with the first inner pad 11 of the first chip 101.

In step S03, a second encapsulant 112 is formed to encapsulate the second chip 102. The second chip 102 has a first surface and a second surface opposite to each other, and a first inner pad 21 and a second inner pad 22 disposed on the first surface, and a third inner pad 23 disposed on the second surface.

In this step, the first substrate is removed, and the exposed surface of the third encapsulant 113 is attached to a second substrate. Then, the second chip 102 is secured on the first encapsulant 111, and a second encapsulant 112 is formed, covering the second chip 102 and exposing its first surface. A second wiring layer 132 is formed on the surface of the first encapsulant 111 opposite the second substrate, connecting the third inner pad 13 of the first chip 101 with the third inner pad 23 of the second chip 102. A third wiring layer 133 is formed on the upper surface of the second encapsulant 112, with the first wiring and the second wiring of the third wiring layer 113 coupled to the first inner pad 21 and the second inner pad 22 of the second chip 102, respectively.

In step S04, the third encapsulant 113 is thinned to expose the lower surface of the first wiring layer 131.

In this step, for example, the exposed surface of the third encapsulant 113 is mechanically ground to remove a portion of the third encapsulant 113 until the lower surface of the first wiring layer 131 is exposed. The thickness of the third encapsulant 113 is uniform, and its exposed surface is flush with the lower surface of the first wiring layer 131, providing a good process foundation for subsequent soldering or connection processes.

FIGS. 4A to 4N show sectional views of various stages of the method for forming the stacked chip package structure according to the second embodiment of the present disclosure. The following provides a more detailed explanation of the packaging method shown in FIG. 3 in conjunction with FIGS. 4A to 4N.

Referring to FIG. 4A, a first substrate 201 is provided, and the first surface of the first chip 101 is adhered face down on the substrate. The first surface of the first chip 101 is formed with a first inner pad 11 and a second inner pad 12, and the second surface is formed with a third inner pad 13. Then, a first encapsulant 111 is formed by injection molding using a plastic material to cover the first chip 101. Then, the exposed surface of the first encapsulant 111 is mechanically ground to remove a portion of the first encapsulant 111 until the first inner pad 11 and the second inner pad 12 of the first chip 101 are exposed.

Referring to FIG. 4B, vertical drilling is performed on the exposed surface of the first encapsulant 111 towards the first substrate 201 to form multiple via holes 103 penetrating the first encapsulant 111. For example, this vertical drilling can be performed using laser drilling or other precision drilling techniques. The purpose of the multiple via holes 103 is to provide conductive vias for the subsequent wiring layer, allowing the inner pads of the first chip 101 to achieve electrical connection with the wiring layer in the subsequent encapsulation layer. The drilling position, diameter, and other parameters of this vertical drilling step are designed according to the specific product characteristics. In this embodiment, since the first chip 101 is a MOS transistor, the first surface of the first chip 101 is formed with a first inner pad 11 for source electrical connection and a second inner pad 12 for gate electrical connection, so this vertical drilling step forms two via holes 103.

Referring to FIG. 4C, conductive metal (such as copper) is filled in the multiple via holes 103 by electroplating to form first parts of the first conductive via 141 and the second conductive via 142. After forming the multiple via holes 103 and completing the electroplating for filling, a metal layer is further formed on the exposed surface of the first encapsulant 111 by electroplating, and the metal layer is etched to form a wiring pattern, thereby forming the first wiring layer 131. The first wiring layer 131 is in direct contact with the first inner pad 11 and the second inner pad 12 of the first chip 101.

Referring to FIG. 4D, a third encapsulant 113 is formed by injection molding using a plastic material to cover the first wiring layer 131.

Referring to FIG. 4E, the first substrate 201 is removed, and the exposed surface of the third encapsulant 113 is attached to a second substrate 202, so that the surface of the first encapsulant 111 faces upward, and the third inner pad 13 on the second surface of the first chip 101 is exposed. Vertical drilling is performed on the exposed surface of the first encapsulant 111 towards the second substrate 202 to form a via hole 104 penetrating the first encapsulant 111 and the third encapsulant 113. For example, this vertical drilling can be performed using laser drilling or other precision drilling techniques. In this embodiment, since the first chip 101 is a MOS transistor, the second surface of the first chip 101 is formed with a third inner pad 13 for drain electrical connection, so this vertical drilling step forms a single via hole 104.

Referring to FIG. 4F, conductive metal (such as copper) is filled in the single via hole 104 by electroplating to form the third conductive via 143. After forming the single via hole 104 and completing the electroplating for filling, a metal layer is further formed on the exposed surface of the first encapsulant 111 by electroplating, and the metal layer is etched to form a wiring pattern, thereby forming the second wiring layer 132. The second wiring layer 132 is in direct contact with the third inner pad 13 of the first chip 101.

Referring to FIG. 4G, the third inner pad 23 of the second chip 102 is bonded on the second wiring layer 132 using a conductive adhesive 105. The first surface of the second chip 102 is formed with a first inner pad 21 and a second inner pad 22, and the second surface is formed with a third inner pad 23. The second chip 102 and the first chip 101 are stacked back-to-back, with their second surfaces facing each other.

Referring to FIG. 4H, a second encapsulant 112 is formed by injection molding using a plastic material, covering the second chip 102 and exposing the first inner pad 21 and the second inner pad 22 on its first surface.

Referring to FIG. 4I, the exposed surface of the second encapsulant 112 is mechanically ground to remove a portion of the plastic material until the first inner pad 21 and the second inner pad 22 of the second chip 102 are exposed. The purpose of this step is to provide a flat surface for the subsequent wiring layer to facilitate electroplating and wiring connection.

Referring to FIG. 4J, vertical drilling is performed on the exposed surface of the second encapsulant 112 towards the first encapsulant 111 to form multiple via holes 106 penetrating the second encapsulant 112. For example, this vertical drilling can be performed using laser drilling or other precision drilling techniques. In this embodiment, since the second chip 102 is a MOS transistor, the first surface of the second chip 102 is formed with a first inner pad 21 for source electrical connection and a second inner pad 22 for gate electrical connection, so this vertical drilling step forms two via holes 106.

Referring to FIG. 4K, conductive metal (such as copper) is filled in the multiple via holes 106 by electroplating to form the second part of the first conductive via 141 and the second conductive via 142. The first part and the second part of the first conductive via 141 are coupled to form a complete conductive via. The first part and the second part of the second conductive via 142 are coupled to form a complete conductive via. After forming the multiple via holes 106 and completing the electroplating filling, a metal layer is further formed on the exposed surface of the second encapsulant 112 by electroplating, and the metal layer is etched to form a wiring pattern, thereby forming the third wiring layer 133. The third wiring layer 133 is in direct contact with the first inner pad 21 and the second inner pad 22 of the second chip 102.

Referring to FIG. 4L, a fourth encapsulant 114 is formed by injection molding using a plastic material to cover the third wiring layer 133.

Referring to FIG. 4M, the second substrate 202 is removed, and the exposed surface of the third encapsulant 113 is mechanically ground to remove a portion of the third encapsulant 113 until the lower surface of the first wiring layer 131 is exposed. The thickness of the third encapsulant 113 is uniform, and its exposed surface is flush with the lower surface of the first wiring layer 131, providing a good process foundation for subsequent soldering or connection processes.

Referring to FIG. 4N, the first external pad 151, the second external pad 152, and the third external pad 153 are formed on the lower surface of the exposed first wiring layer 131 by electroplating. The first external pad 151 is electrically coupled to the first inner pad 11 of the first chip 101 and the first inner pad 21 of the second chip 102, the second external pad 152 is electrically coupled to the second inner pad 12 of the first chip 101 and the second inner pad 22 of the second chip 102, and the third external pad 153 is electrically coupled to the third inner pad 13 of the first chip 101 and the third inner pad 23 of the second chip 102. This step simplifies the external connection design of the stacked chip package structure by collectively leading out multiple inner pads to external pads, reducing the number of external pads and improving the compactness and production efficiency of the package structure.

In any step in which an electroplating process is used in the present disclosure, a plating protection layer is first formed on the surface using photolithography techniques such as exposure and development, and then a metal seed layer is formed in the area to be plated by sputtering or copper deposition. The metal seed layer is made of copper or other metal materials, ensuring the adhesion between the subsequently plated metal and the plastic encapsulant, while providing a surface for conductive ion attachment during plating, ensuring the plating effect. The use of photoresist during the plating process is also well known in the field.

In any step in which an encapsulation processes is used in the present disclosure, encapsulation is formed by injection molding using a plastic encapsulant. The plastic encapsulant used in the present disclosure is EMC (epoxy molding compound), which is low-cost and has good curing performance.

It is understood that the present disclosure is described through some embodiments, and those skilled in the art are aware that various changes or equivalent replacements can be made to these features and embodiments without departing from the spirit and scope of the present disclosure. Additionally, modifications can be made to these features and embodiments to adapt to specific situations and materials without departing from the spirit and scope of the present disclosure. Therefore, the present disclosure is not limited to the specific embodiments disclosed herein, and all embodiments falling within the scope of the claims of the present disclosure are within the scope of protection of the present disclosure.

What is claimed is:

1. A stacked chip package structure comprising:
a first encapsulant and a second encapsulant stacked on the first encapsulant, the first encapsulant encapsulating a first chip and the second encapsulant encapsulating a second chip, each of the first chip and the second chip having a first surface and a second surface opposite to the first surface, and a first inner pad on the first surface and a third inner pad on the second surface, wherein the second surface of the first chip faces the second surface of the second chip face; and
a third encapsulant disposed below the first encapsulant and encapsulating a first wiring layer, the first wiring layer electrically coupling the first inner pad of the first chip and the first inner pad of the second chip to a first external pad,
wherein the first wiring layer penetrates the third encapsulant and is in direct contact with the first inner pad of the first chip and the first external pad.

2. The stacked chip package structure according to claim 1, further comprising:
a second wiring layer disposed above the first encapsulant and coupling the third inner pad of the first chip with the third inner pad of the second chip; and
a third conductive via penetrating the first encapsulant and the third encapsulant, the third conductive via coupling the second wiring layer with a third external pad.

3. The stacked chip package structure according to claim 1, further comprising:
a third wiring layer disposed above the second encapsulant, wherein a first wiring of the third wiring layer is coupled to the first inner pad of the second chip; and
a first conductive via penetrating the first encapsulant and the second encapsulant, the first conductive via coupling the first wiring of the third wiring layer with the first wiring layer.

4. The stacked chip package structure according to claim 3, wherein the first conductive via comprises a first section and a second section, the first section penetrating the first encapsulant and the second section penetrating the second encapsulant.

5. The stacked chip package structure according to claim 3, wherein each of the first chip and the second chip has a second inner pad on the first surface, and a second wiring of the third wiring layer is coupled with the second inner pad of the second chip.

6. The stacked chip package structure according to claim 5, further comprising:
a third conductive via penetrating the first encapsulant and the second encapsulant, the third conductive via coupling the second wiring of the third wiring layer to the first wiring layer.

7. The stacked chip package structure according to claim 6, wherein the third conductive via comprises a first section and a second section, the first section penetrating the first encapsulant and the second section penetrating the second encapsulant, respectively.

8. The stacked chip package structure according to claim 1, wherein the first chip and the second chip are a first MOS transistor and a second MOS transistor, respectively.

9. The stacked chip package structure according to claim 8, wherein the first inner pad is a source pad of the first MOS transistor or the second MOS transistor, and the third inner pad is a drain pad of the first MOS transistor or the second MOS transistor.

10. A method of forming a stacked chip package structure, comprising:
forming a first encapsulant to encapsulate a first chip;
forming a third encapsulant to encapsulate a first wiring layer; and
forming a second encapsulant to encapsulate a second chip,
wherein each of the first chip and the second chip has a first surface and a second surface opposite to the first surface, a first inner pad on the first surface, and a third inner pad on the second surface, and the second surface of the first chip faces the second surface of the second chip,
wherein the first wiring layer penetrates the third encapsulant and is in direct contact with the first inner pad of the first chip and a first external pad.

11. The method according to claim 10, wherein the step of forming the first encapsulant to encapsulate the first chip comprises:
providing a first substrate;
attaching the second surface of the first chip on the first substrate; and
forming the first encapsulant to cover the first chip and expose the first surface of the first chip.

12. The method according to claim 11, wherein the step of forming the third encapsulant to encapsulate the first wiring layer comprises:
forming the first wiring layer on a surface of the first encapsulant opposite the first substrate;
forming the third encapsulant on the first encapsulant, the third encapsulant covering the first wiring layer; and
thinning the third encapsulant so that the first wiring layer penetrates the third encapsulant.

13. The method according to claim 12, wherein the step of forming the second encapsulant to encapsulate the second chip comprises:
removing the first substrate;
attaching the exposed surface of the third encapsulant on a second substrate;
securing the second chip on the first encapsulant; and
forming the second encapsulant to cover the second chip and expose the first surface of the second chip.

14. The method according to claim 13, after attaching the exposed surface of the third encapsulant on the second substrate, further comprising:
forming a second wiring layer on a surface of the first encapsulant opposite the second substrate; and
forming a third conductive via penetrating the first encapsulant and the third encapsulant.

15. The method according to claim 13, further comprising:
forming a third wiring layer on the exposed surface of the second encapsulant; and
forming a fourth encapsulant to cover the third wiring layer.

16. The method according to claim 15, wherein each of the first chip and the second chip has a second inner pad on the first surface, and a second wiring of the third wiring layer is coupled to the second inner pad of the second chip, the method further comprising:
forming a first conductive via penetrating the first encapsulant and the second encapsulant to couple a first wiring of the third wiring layer to the first wiring layer; and/or
forming a third conductive via penetrating the first encapsulant and the second encapsulant to couple the second wiring of the third wiring layer to the first wiring layer.

17. The method according to claim 10, wherein the first chip and the second chip are a first MOS transistor and a second MOS transistor, respectively.

18. The method according to claim 17, wherein the first inner pad is a source pad of the first MOS transistor or the second MOS transistor, and the third inner pad is a drain pad of the first MOS transistor or the second MOS transistor.

19. The method according to claim 10, wherein any encapsulant in the stacked chip package structure is formed by:
forming the encapsulant by injection molding using a plastic material; and
curing and shaping the plastic material by a molding process.

20. The method according to claim 10, wherein any wiring layer in the stacked chip package structure is formed by electroplating metal.
